(19) United States
(12) Patent Application Publication
(10) Pub. No.: US 2019/0293741 A1
(43) Pub. Date: Sep. 26, 2019

(54) Personal protection measuring device

(71) Applicant: Narda Safety Test Solutions GmbH, Pfullingen (DE)

(72) Inventors: Michael Späth, Pfullingen (DE); Johannes Heusel, Mössingen (DE)

(21) Appl. No.: 15/928,392

(22) Filed: Mar. 22, 2018

(51) Int. Cl. G01R 35/00; G01R 29/08; G01R 29/12; G01R 33/02

(52) U.S. Cl. CPC G01R 35/00; G01R 33/0206; G01R 29/12; G01R 29/0857

(57) ABSTRACT

A personal protection measuring device for protecting persons in electromagnetic fields, comprising a sensor unit including one or more sensor elements used as E-field and/or H-field sensors, an electronic control and evaluation unit and a display, wherein the sensors comprise resistors and diodes connected in series, wherein a test apparatus is provided for checking the functional capability of the sensor elements independently from external surrounding electromagnetic fields.

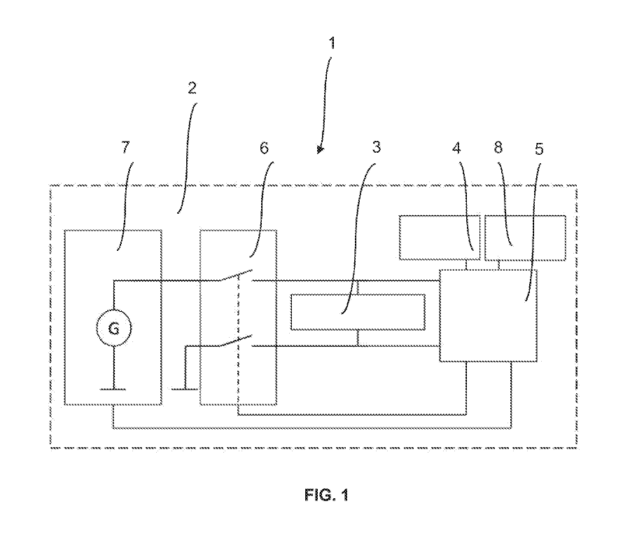

### TECHNICAL FIELD

The present invention relates to a personal protection measuring device for protecting persons in electromagnetic fields, comprising a sensor unit including one or more sensor elements used as E-field and/or H-field sensors, an electronic control and evaluation unit, and a display, wherein the sensors comprise resistors and diodes connected in series. The invention furthermore relates to a method for operating such a personal protection measuring device.

### BACKGROUND ART

Laws, as well as national regulations and recommendations, are in place for protection and safety at the workplace, which provide for exposure limits for persons working in electromagnetic fields. For this purpose, suitable measuring devices are available for the respective uses and industries. Depending on the application, what are known as broadband measuring devices or personal monitors are used, which are designed as described at the outset. Personal protection measuring devices are known which measure either the electric fields (E-field) or the magnetic fields (H-field) separately in different frequency ranges. These measuring devices are usually compact portable measuring devices comprising a measuring device housing, which is to be held manually, and in which measuring and evaluation electronics including storage means, an optical and/or acoustic display and operating elements are present, and to which, depending on the application, suitable sensors can be connected. Such personal protection measuring devices are typically used in a targeted manner to analyze a certain region for the presence of E-field and/or H-field pollution. Additionally, measuring devices are available which, in particular, when worn on the body as immediate handy warning devices (monitors), warn against excessively high electric and magnetic fields at work, and thus measure both the E-field and the H-field. In these devices, the sensors are integrated in the measuring device housing. In addition to the use as a warning device worn on the body, such personal protection measuring devices can furthermore be used as a monitoring device so as to check the area in which people are present in advance for compliance with limit values, in a manner similar to that of the above-described devices. Furthermore, due to the structurally small configuration thereof, such a device can also be used to search for leaks on waveguide and coaxial screw joints.

### SUMMARY

It is the object of the sensors and of the sensor unit to detect the incident field and convert it into a measurable DC voltage. For this purpose, antenna elements (detectors) are interconnected with diodes (rectifiers). One particular problem of these devices is that the sensor elements in the sensor unit burn out due to excessive exposure in corresponding fields or can become damaged by mechanical stresses. Once the sensors are damaged, the devices no longer indicate correct values, and there is the risk of the persons to be protected being exposed to impermissibly high electromagnetic fields. So as to preclude this risk, it has previously been recommended to expose the sensors to a reference field having a known field strength prior to measuring use, and to test whether the device actually displays this reference value. This procedure is very complex since a reference source must be carried along, and this procedure presupposes that the sensor is only exposed to the reference field, and not perhaps to other fields acting from the outside, which is to say that the sensor must be shielded. The step of ensuring the necessary shielding, in particular, makes this prior test cumbersome and complex.

It is therefore the object of the present invention to propose a personal protection measuring device that allows the user to repeatedly test the measuring device for proper function at the site, in the actual environment, without additional shielding measures.

This object is achieved according to the invention by a personal protection measuring device as described herein. The object is furthermore achieved by a method for operating such a personal protection measuring device.

According to the invention, a test apparatus for checking the functional capability of the sensor elements independently from external surrounding electromagnetic fields is provided. Depending on the embodiment of the personal protection measuring device, the test apparatus may be integrated in the housing of the measuring device, or in the measuring probe to be connected to the measuring device housing. For the test apparatus to be able to carry out the check of the functional capability of the sensor elements independently from external surrounding electromagnetic fields, it is necessary that the test apparatus operates with signals that can be clearly distinguished from the measurement signals.

According to a preferred design of the personal protection measuring device, the test apparatus comprises a signal generator for generating a test signal on one or more sensor elements (hereafter referred to, for purposes of simplification, as a sensor unit). In the simplest case, the test signal is a DC voltage. However, it may also be designed as a pulsed, modulated, encoded, clocked signal or as an AC voltage. In the event of damage, the test signal applied to the sensor unit is modified by the sensor unit such that it is possible to infer the condition of the sensor unit via the evaluation device wherein, depending on the test signal, a reference signal or a reference value is stored in a memory, preferably in a device-specific manner. The test signal is applied directly to the sensor unit. Since the sensors are usually made either completely (E-field sensor) or to a large degree (H-field sensors) of resistors and diodes connected in series, it is possible, in the simplest case, using a DC voltage as the test signal, to infer the condition of the sensor unit, such as open circuits or short circuits in one or more diodes based on the detected test voltage due to the voltage drop across the sensor unit. In this way, it is possible to identify defects in the sensor unit caused by oscillations or excessive mechanical stresses (open circuits), or by excessive electromagnetic fields (short circuits in the diodes). Checking an E-field sensor and an H-field sensor differs only in the level of the test voltage. The comparison of the test signal at the one or more sensor elements to a stored reference signal or reference value takes place by way of the control and evaluation unit, which serves as an evaluation unit for this purpose.

Advantageously, the test signal has a characteristic which differs from that of the sensor voltage generated by the electromagnetic field. Depending on the type of the test signal, this may be the voltage level, the frequency or a digital encoding of the test signal. The test signal output by the signal generator is several times greater, in the case of a DC voltage, than the sensor voltage generated by the electromagnetic field, so that the functional capability can also be checked when the device is already located in an area having of increased field strength.

Since the difference in the voltage drop is only a few millivolts for a short circuited diode, and the differences in voltage caused by component tolerances may be larger, the reference signal or the reference value is advantageously device-specific, and is ascertained upon commissioning of the personal protection measuring device, and stored in a device memory.

According to a further preferred design of the personal protection measuring device, the control and evaluation unit ascertains the present device condition, preferably after the personal protection measuring device has been switched on. For this purpose, the control and evaluation unit prompts the measurement of the present field strength, the no-load test signal and, optionally, the present temperature, which may be required for temperature compensation. Preferably, but not imperatively, according to an advantageous design of the personal protection measuring device, after the present device condition has been established, a test signal is applied to the sensor unit by the control and evaluation unit via the test apparatus, and a signal dependent thereon, or a signal value dependent thereon, is ascertained as described above.

The control and evaluation unit compares the ascertained signal, or the ascertained signal value, to the stored reference signal or reference signal value from the sensor unit and, according to a preferred design of the personal protection measuring device, effectuates either the start of the normal measuring operation or shut-off of the personal protection measuring device, as a function of the comparison. The comparison can optionally be carried out together with the temperature compensation. This reliably notifies the user when a malfunction of the personal protection measuring device exists.

Prior to the shut-off, the control and evaluation unit preferably prompts output of a defined signal acoustically and/or visually by way of a corresponding display apparatus, and preferably prompts an entry in a, preferably internal, data logger containing the measured values from the check of the sensor unit.

Advantageously, the test signal is carried out prior to conducting a measurement of the electric/magnetic/electromagnetic fields, so as to ensure the operator, prior to commissioning, that the personal protection measuring device is functioning correctly. It is also possible to interrupt an ongoing process of measuring the fields and, in the interim, carry out a test of the functional capability of the sensor unit, and to subsequently continue the measurement with the personal protection measuring device. This can take place automatically in a time-controlled manner, or as a function of predefined peak values of the measurement of the fields that has just taken place, or manually, by the user.

According to a preferred design of the personal protection measuring device, the test apparatus comprises a voltage generator for generating a test voltage on one or more sensor elements, and an evaluation apparatus for comparing the voltage drop across the one sensor element, or the multiple sensor elements, to a stored reference voltage value. This is the option that is the easiest to implement, wherein advantageously the test voltage has a voltage level that differs considerably from the sensor voltage generated by the electromagnetic field.

According to the method for operating the personal protection measuring device, in a preferred embodiment, the device condition with respect to the present field strength, the test voltage in the idle state and, optionally, the present temperature is ascertained after the personal protection measuring device has been switched on, thereafter the test voltage is applied to one or more sensor elements and is measured and compared to one or more reference voltages and, as a function of the comparison result, the normal measuring operation is started or the device is shut off. As was already described, it is also possible for checking of the device condition to be omitted or for a check of the functional capability to take place during a field measurement.

The present invention thus enables automatic testing, so that carrying along a reference source and testing the personal protection measuring device in a shielded environment can be dispensed with. This constitutes a considerable simplification and higher reliability for the measurement of electromagnetic fields, wherein this may take place independently of the surrounding electromagnetic fields.

The features and feature combinations mentioned above in the description, and the features and feature combinations mentioned hereafter in the description of the figures and/or shown only in the FIGURES, can be used not only in the respective indicated combinations, but also in other combinations, or alone. All of the features and/or advantages that are apparent from the claims, the description or the drawing, including design details, arrangement in terms of space, and method steps can be essential to the invention, both alone and in a wide variety of combinations. It is not necessary for all the features recited in the claims to be implemented to carry out the invention. It is also possible to replace individual features of the independent or dependent claims with other disclosed features or feature combinations.

### BRIEF DESCRIPTION OF THE DRAWING

The FIGURE is a schematic block diagram of a personal protection measuring device according to an exemplary embodiment.

### DETAILED DESCRIPTION

The invention will be briefly described hereafter based on the FIGURE. Based on a schematic block diagram, the FIGURE shows the composition as it may be implemented, for example, in a personal protection measuring device 1 in the form of a personal monitor that is worn on the body. In this exemplary embodiment, in addition to the sensor unit 3, which is composed of multiple sensor elements, and the control and evaluation unit 5, which is present as a rule, and a visual display 4, a test signal generator 7 comprising an associated switching apparatus 6 is integrated in a housing 2, which is indicated by dotted lines, and electrically connected. In this exemplary embodiment, the sensor unit 3, in the known manner, comprises an E-field sensor and an H-field sensor, each of which has a three-axis (isotropic) design. All three axes are respectively connected in series and comprise resistors and diodes connected in series. Of course, the control and evaluation unit itself also comprises operating elements, unless these are implemented via the display, and suitable storage means. A test apparatus, which in the exemplary embodiment comprises the test signal generator 7, the switch 6, and the control and evaluation unit 5 as the evaluation apparatus, is provided for checking the personal protection measuring device 1 for functional capability. In the exemplary embodiment, the test signal generator 7 supplies a DC voltage, which is applied to the sensor unit 3 via the switch 6. The control and evaluation unit 5, which is also connected to the test signal generator 7 and the switching apparatus 6, compares the voltage present at the sensor unit 3 to a stored reference voltage to establish whether the sensor unit 3 is damaged. If the voltage at the sensor unit 3 is within a certain predefined range compared to the stored reference voltage, the normal measuring operation is started after a settling time has been taken into consideration. If the voltage at the sensor unit 3 is too high compared to the reference voltage, it is to be assumed that an open circuit is present or, in the other case, a short circuit of one or more diodes. Both cause a defined signal tone to be emitted via an acoustic signal transmitter 8. Moreover, an entry occurs in a data memory (data logger), which is integrated into the control and evaluation unit 5, containing the measured values from the check (sensor voltage prior to the check, unloaded/loaded test voltage, and temperature). Thereafter, the personal protection measuring device 1 shuts off.

1. A personal protection measuring device for protecting persons in electromagnetic fields, comprising a sensor unit including one or more sensor elements used as E-field and/or H-field sensors, an electronic control and evaluation unit and a display, the sensors comprising resistors and diodes connected in series, wherein a test apparatus for checking the functional capability of the sensor elements independently from external surrounding electromagnetic fields.

2. The personal protection measuring device according to claim 1, wherein the test apparatus comprises a signal generator for generating a test signal at the sensor unit, and an evaluation apparatus for comparing the test signal at the sensor unit to a stored reference signal or reference value.

3. The personal protection measuring device according to claim 2, wherein the test signal has a characteristic which differs from that of the sensor voltage generated by the electromagnetic field.

4. The personal protection measuring device according to claim 2, wherein the reference signal or the reference value is device-specific.

5. The personal protection measuring device according to claim 1, wherein after the device has been switched on, the control and evaluation unit, ascertains the present field strength and the no-load test signal for establishing the present device condition.

6. The personal protection measuring device according to claim 1, wherein after the present device condition has been established, the control and evaluation unit, applies a test signal to the sensor unit via the test apparatus, and ascertains a signal dependent thereon or a signal value dependent thereon.

7. The personal protection measuring device according to claim 6, wherein the control and evaluation unit compares the ascertained signal, or the ascertained signal value, to the stored reference signal or reference signal value from the sensor unit, and either starts the normal measuring operation or switches the personal protection measuring device off, as a function of the comparison.

8. The personal protection measuring device according to claim 7, wherein, prior to the shut-off, the control and evaluation unit prompts the output of a defined signal acoustically and/or visually.

9. The personal protection measuring device according to claim 1, wherein the test apparatus comprises a voltage generator for generating a test voltage at the sensor unit, and an evaluation apparatus for comparing the voltage drop across the sensor unit to a stored reference voltage value.

10. The personal protection device according to claim 9, wherein the test voltage has a voltage level that differs from the sensor voltage generated by the electromagnetic field.

11. A method for operating a personal protection measuring device according claim 1, wherein the device condition with respect to the present field strength, and the test voltage in the idle state, is ascertained after the personal protection measuring device has been switched on, and thereafter the test voltage is applied to the sensor unit and is measured and compared to one or more reference voltages and, as a function of the comparison result, the normal measuring operation is started or the personal protection measuring device is shut off.
